(19) United States
(12) Patent Application Publication
(10) Pub. No.: US 2011/0157038 A1
(43) Pub. Date: Jun. 30, 2011

(54) TOUCH PANEL AND FABRICATION METHOD THEREOF

(75) Inventor: CHEN FENG, Beijing (CN)

(73) Assignee: BEIJING FUNATE INNOVATION TECHNOLOGY CO., LTD., Beijing (CN)

(21) Appl. No.: 12/848,312

(22) Filed: Aug. 2, 2010

(30) Foreign Application Priority Data
Dec. 28, 2009 (CN) 200910260284.7

(51) Int. Cl. G06F 3/041; H03K 17/94; H01J 9/00

(52) U.S. Cl. 345/173; 445/24; 341/20

(57) ABSTRACT

A touch panel includes a substrate, an adhesive layer, and a transparent conductive layer fixed on the substrate by the adhesive layer. The conductive layer includes a carbon nanotube layer with a surface roughness Ra thereof less than or equal to about 0.1 μm. A fabrication method for a touch panel includes reducing the surface roughness Ra of the carbon nanotube layer to less than or equal to about 0.1 μm by applying pressure on the carbon nanotube layer via a press tool with a flat surface. A surface roughness Ra of the flat surface is less than or equal to about 0.1 μm.

### RELATED APPLICATIONS

This application claims all benefits accruing under 35 U.S.C. §119 from China Patent Application No. 200910260284.7, filed on Dec. 28, 2009 in the China Intellectual Property Office, the disclosure of which is incorporated herein by reference.

### BACKGROUND

1. Technical Field

The present disclosure relates to touch panels and methods for making the same and, in particular, to a touch panel based on carbon nanotubes and a fabrication method thereof.

2. Discussion of Related Art

Various electronic apparatuses such as mobile phones, car navigation systems, and the like are equipped with optically transparent touch panels applied over display devices such as liquid crystal panels. The electronic apparatus is operated when contact is made with the touch panel corresponding to elements appearing on the display device. A demand thus exists for such touch panels to maximize visibility and reliability in operation.

Resistive, capacitive, infrared, and surface acoustic wave touch panels have been developed. Resistive and capacitive touch panels are widely applied because of the higher accuracy and low cost of production.

A resistive or capacitive touch panel often includes a layer of indium tin oxide (ITO) as an optically transparent conductive layer. The ITO layer is generally formed by ion beam sputtering, a relatively complicated undertaking. Furthermore, the ITO layer has poor wearability, low chemical endurance, and uneven resistance over the entire area of the panel, as well as relatively low transparency. Such characteristics of the ITO layer can significantly impair sensitivity, accuracy, and brightness.

### BRIEF DESCRIPTION OF THE DRAWINGS

Many aspects of the embodiments can be better understood with references to the following drawings. The components in the drawings are not necessarily drawn to scale, the emphasis instead placed upon clearly illustrating the principles of the embodiments. Moreover, in the drawings, like reference numerals designate corresponding parts throughout the several views.

FIG. 1 is a schematic view of one embodiment of a touch panel.

FIG. 2 is a cross-section along broken line II-II of the touch panel of FIG. 1.

FIG. 3 shows a Scanning Electron Microscope (SEM) image of a transparent conductive layer in the touch panel of FIG. 2.

FIG. 4 is a surface configuration view of the transparent conductive layer of FIG. 3.

FIG. 5 is an enlarged optical path view of circled portion V of FIG. 2.

FIG. 6 is a surface configuration view of the transparent conductive layer of FIG. 3, wherein a surface roughness arithmetic average deviation (Ra) of the transparent conductive layer exceeds 0.1 micrometer (μm).

FIG. 7 is an enlarged optical path view of circled portion V of FIG. 2, wherein a surface roughness Ra of the transparent conductive layer exceeds 0.1 μm.

FIG. 8 illustrates steps of one embodiment of a fabrication method of a touch panel.

FIG. 9 is an exploded, isometric view of another embodiment of a touch panel.

FIG. 10 is a schematic, assembled view of the touch panel of FIG. 9.

FIG. 11 illustrates steps of another embodiment of a fabrication method of a touch panel.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

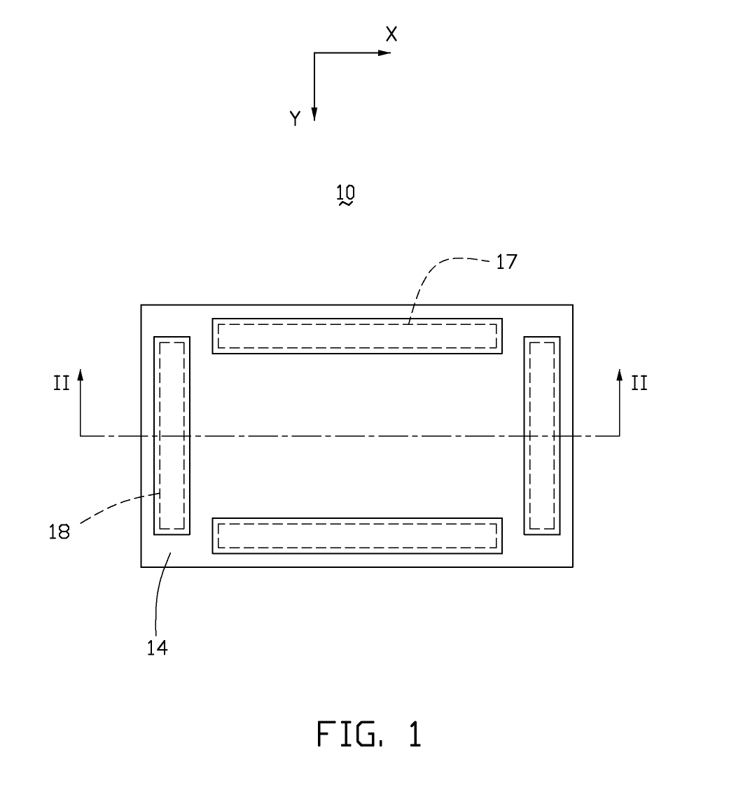

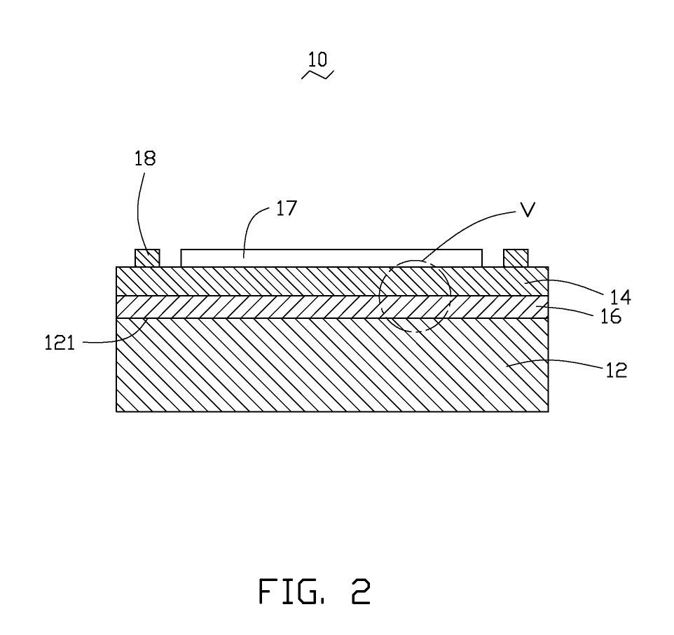

Referring to FIG. 1 and FIG. 2, one embodiment of a capacitive touch panel 10 includes a substrate 12, a transparent conductive layer 14, an adhesive layer 16, two first electrodes 18, and two second electrodes 17. The substrate 12 includes a top surface 121. The transparent conductive layer 14 is placed on the top surface 121 of the substrate 12 and fixed by the adhesive layer 16. The first electrodes 18 are spaced from each other and electrically connected to the transparent conductive layer 14. The second electrodes 17 are spaced from each other and electrically connected to the transparent conductive layer 14. Thus, an equipotential plane is formed on the transparent conductive layer 14.

The substrate 12 can have a curved structure or a planar structure and functions as a supporter with suitable transparency. The substrate 12 may be made of a rigid material or a flexible material. The rigid material can be glass, silicon, diamond, plastic, or other material. The flexible material can be polycarbonate (PC), polymethyl methacrylate acrylic (PMMA), polyethylene terephthalate (PET), polyether polysulfones (PES), polyvinyl polychloride (PVC), benzocyclobutenes (BCB), polyesters, or acrylic resins. In one embodiment, the substrate 12 is made of PC.

The adhesive layer 16 can be transparent and may include materials having low melting points. The adhesive layer 16 is configured for fixing the transparent conductive layer 14 on the top surface 121 of the substrate 12 tightly. The adhesive layer 16 may be a thermoplastic adhesive or an ultraviolet rays adhesive, such as PVC or PMMA. A thickness of the adhesive layer 16 can be selected according to need, so long as the adhesive layer 16 can hold the transparent conductive layer 14 on the substrate 12, and part of the transparent conductive layer 14 protrudes from the adhesive layer 16. The thickness of the adhesive layer 16 is in a range from about 1 nanometer (nm) to about 500 μm. Specifically, the thickness of the adhesive layer 16 is in a range from about 1 μm to about 2 μm. In one embodiment, the adhesive layer 16 is made of PMMA, and the thickness of the adhesive layer 16 is about 1.5 μm.

The transparent conductive layer 14 can be a carbon nanotube layer. The carbon nanotube layer can include a plurality of carbon nanotubes substantially parallel to a surface of the carbon nanotube layer. A thickness of the carbon nanotube layer can be selected according to need, and can be in a range from about 0.5 nm to about 100 μm. Specifically, the thickness of the carbon nanotube layer may be in a range from about 100 nm to about 200 nm. The carbon nanotubes are uniformly distributed in the carbon nanotube layer, and have excellent flexibility. Accordingly, the carbon nanotube layer has excellent flexibility, and can bend to any shape without fracturing.

The carbon nanotube layer can be formed by ordered or disordered carbon nanotubes. The ordered carbon nanotube layer consists of ordered carbon nanotubes. Ordered carbon nanotube layers include films on which the carbon nanotubes are substantially arranged along a primary direction. Examples include films wherein the carbon nanotubes are arranged approximately along a same direction or have two or more sections within each of which the carbon nanotubes are arranged approximately along a same direction (different sections can have different directions).

The carbon nanotube layer can include one or more layers of carbon nanotube films. If the carbon nanotube layer includes multiple carbon nanotube films, the carbon nanotube films are stacked. The carbon nanotube layer employs more carbon nanotube films to increase the tensile strength of the carbon nanotube layer. The carbon nanotube film has a thickness in an approximate range from about 0.5 nm to about 100 millimeters (mm) The carbon nanotube film may have a free-standing structure. The term “free-standing structure” includes, but is not limited to, a structure capable of being supported by itself and does not need a substrate to lie on. For example, the carbon nanotube film can be lifted by one point thereof such as a corner without sustaining damage under its own weight. The carbon nanotube film may be a drawn carbon nanotube film, pressed carbon nanotube film, or flocculated carbon nanotube film.

Drawn Carbon Nanotube Film

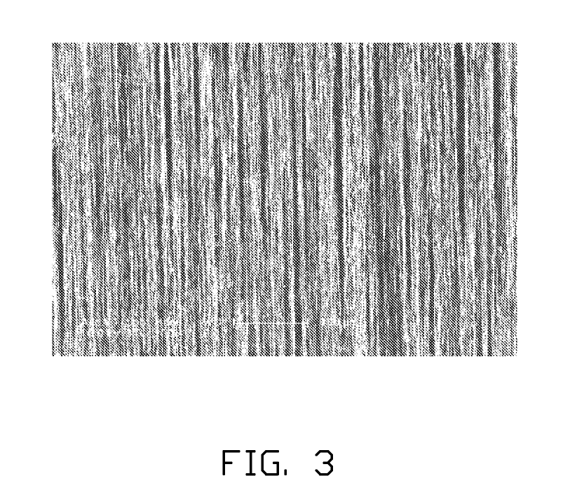

Referring to FIG. 3, the carbon nanotubes in the drawn carbon nanotube film are oriented along a same preferred orientation and are approximately parallel to each other. In this connection, the term “approximately” as used herein means that it is impossible and unnecessary that every carbon nanotube in the carbon nanotube films are parallel to each other, because factors such as a change in drawing speed or non-uniform drawing force on the carbon nanotube film when the carbon nanotube film is drawn from a carbon nanotube array, can affect the orientation of the carbon nanotubes. A drawn carbon nanotube film can be drawn from a carbon nanotube array to form the ordered carbon nanotube film. Examples of drawn carbon nanotube film are taught by U.S. Pat. No. 7,045,108 to Jiang et al.. The drawn carbon nanotube film includes a plurality of successive and oriented carbon nanotubes joined end-to-end by van der Waals force therebetween. The drawn carbon nanotube film is a free-standing film. The carbon nanotube film can be treated with an organic solvent to increase the mechanical strength of the carbon nanotube film and reduce the coefficient of friction of the carbon nanotube film. A thickness of the carbon nanotube film can range from about 0.5 nm to about 100 μm.

Understandably, the carbon nanotube film structure may further include at least two stacked carbon nanotube films. Additionally, when the carbon nanotubes in the carbon nanotube film are aligned along one preferred orientation (e.g., the drawn carbon nanotube film), an angle can be formed between the orientation of carbon nanotubes in adjacent films. Adjacent carbon nanotube films can only be combined by the van der Waals force therebetween. The number of the layers of the carbon nanotube films is not limited. However the specific surface area will decrease as the thickness of the carbon nanotube structure increases. An angle between the aligned axes of the carbon nanotubes in two adjacent carbon nanotube films can range from about 0 degrees to about 90 degrees.

Pressed Carbon Nanotube Film

The ordered carbon nanotube film may be a pressed carbon nanotube film having a number of carbon nanotubes substantially arranged along the same direction. The carbon nanotubes in the pressed carbon nanotube film can rest upon each other. Adjacent carbon nanotubes are attracted to each other and combined by van der Waals force. In one embodiment, the angle between a primary alignment direction of the carbon nanotubes and a surface of the pressed carbon nanotube film is 0 degrees to approximately 15 degrees, with the angle decreasing with increasing applied pressure. The thickness of the pressed carbon nanotube film can range from about 0.5 nm to about 1 mm. Examples of a pressed carbon nanotube film are taught in US application 2008/0299031A1 to Liu et al. The pressed carbon nanotube film can be formed by providing an array of carbon nanotubes forming a substrate, and providing pressure on the array of carbon nanotubes.

The pressed carbon nanotube film also may be a disordered carbon nanotube film, which has a number of carbon nanotubes arranged along different directions. The pressed carbon nanotube film can be a free-standing carbon nanotube film. When the carbon nanotubes in the pressed carbon nanotube film are arranged along different directions, the pressed carbon nanotube film can be isotropic. The, thickness of the pressed carbon nanotube film ranges from about 0.5 nm to about 1 mm. Examples of the pressed carbon nanotube film are taught by US application 2008/0299031A1 to Liu et al.

Flocculated Carbon Nanotube Film

The disordered carbon nanotube film consists of the carbon nanotubes arranged in a disorderly fashion. Disordered carbon nanotube films include randomly aligned carbon nanotubes. If the disordered carbon nanotube film comprises a film wherein the number of the carbon nanotubes aligned in every direction is substantially equal, the disordered carbon nanotube film can be isotropic. The disordered carbon nanotubes can be entangled with each other and/or be substantially parallel to a surface of the disordered carbon nanotube film. The disordered carbon nanotube film may be a flocculated carbon nanotube film. The flocculated carbon nanotube film can include a plurality of long, curved, disordered entangled carbon nanotubes. Further, the carbon nanotubes in the flocculated carbon nanotube film can be isotropic. The carbon nanotubes can be substantially uniformly dispersed in the flocculated carbon nanotube film. Adjacent carbon nanotubes are attracted by van der Waals force to form an entangled structure with micropores defined therein. It is understood that the flocculated carbon nanotube film is porous. Sizes of the micropores can be less than 10 μm. Because the carbon nanotubes in the flocculated carbon nanotube film are entangled, the carbon nanotube structure employing the flocculated carbon nanotube film has excellent durability, and can be fashioned into desired shapes with a low risk to the integrity of the flocculated carbon nanotube film. The thickness of the flocculated carbon nanotube film can range from about 0.5 nm to about 1 mm. The flocculated carbon nanotube film can be provided by flocculating carbon nanotubes in a solvent to acquire a flocculated carbon nanotube structure, separating the flocculated carbon nanotube structure from the solvent, and shaping the separated flocculated carbon nanotube structure into the flocculated carbon nanotube film in which the carbon nanotubes are entangled and isotropic.

A length and a width of the flocculated carbon nanotube film can be arbitrarily set according to need. A thickness of the flocculated carbon nanotube film can range from about 0.5 nm to about 100 mm. The carbon nanotubes in the flocculated carbon nanotube film can be single-walled, double-walled, multi-walled carbon nanotubes, or combinations thereof. The diameters of the single-walled carbon nanotubes, the double-walled carbon nanotubes, and the multi-walled carbon nanotubes can, respectively, be in a range from about 0.5 nm to about 50 nm, about 1 nm to about 50 nm, and about 1.5 nm to about 50 nm.

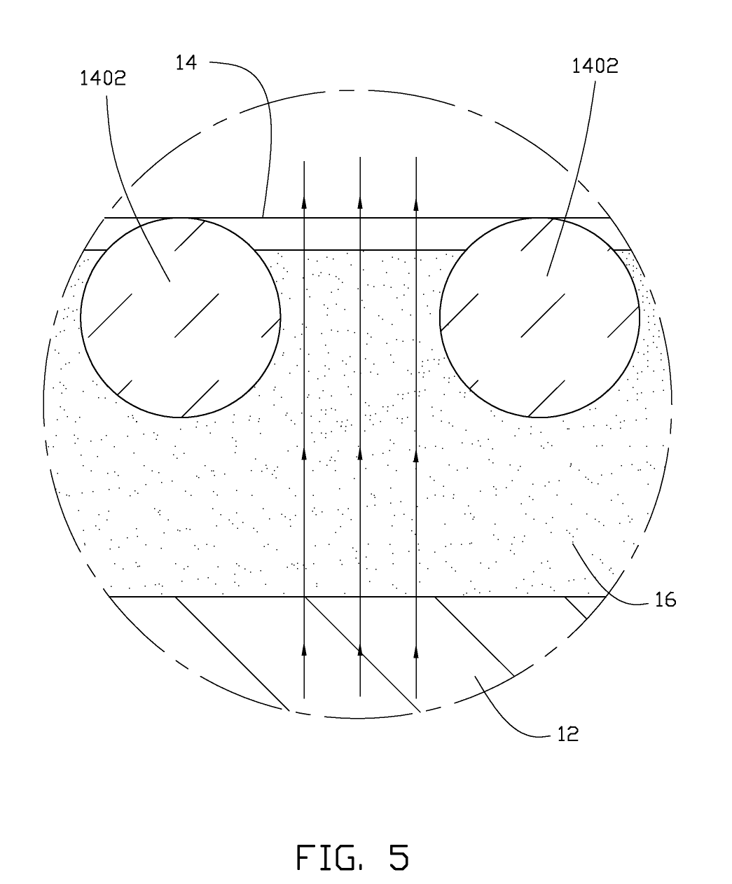

Referring to FIG. 5, the transparent layer 14 is a carbon nanotube layer. The carbon nanotube layer is composed of a plurality of carbon nanotubes 1402. A plurality of micropores is defined in adjacent carbon nanotubes of the plurality of carbon nanotubes 1402. The transparent conductive layer 14 can be attached to the substrate 12 by the adhesive layer 16 by an external force. The material of the adhesive layer 16 can infiltrate into the plurality of micropores of the transparent layer 14 to substantially level the transparent conductive layer 14. Each of the plurality of carbon nanotubes 1402 of the carbon nanotube layer is partly embedded in the adhesive layer 16, and partly exposed to the adhesive layer 16. The carbon nanotubes 1402 embedded in the adhesive layer 16 are fixed to the substrate 12 by the adhesive layer 16. The carbon nanotubes 1402 exposed to the adhesive layer 16 can be electrically conductive.

The transparent conductive layer 14, that is, a surface of the carbon nanotube layer exposed to the adhesive layer 16, has low surface roughness. The surface roughness of the transparent conductive layer 14 should be treated, so that color fringes due to refraction of the transparent conductive layer 14 during use of touch panel 10 will not be obvious or even avoided.

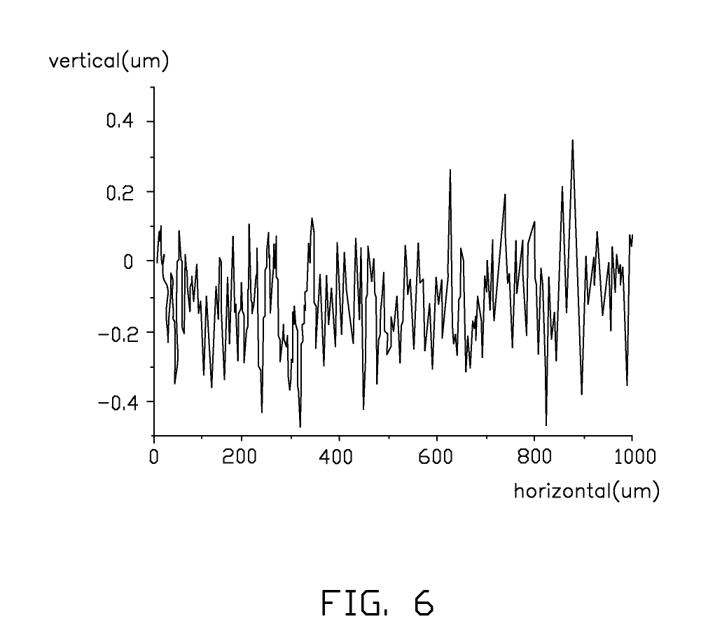

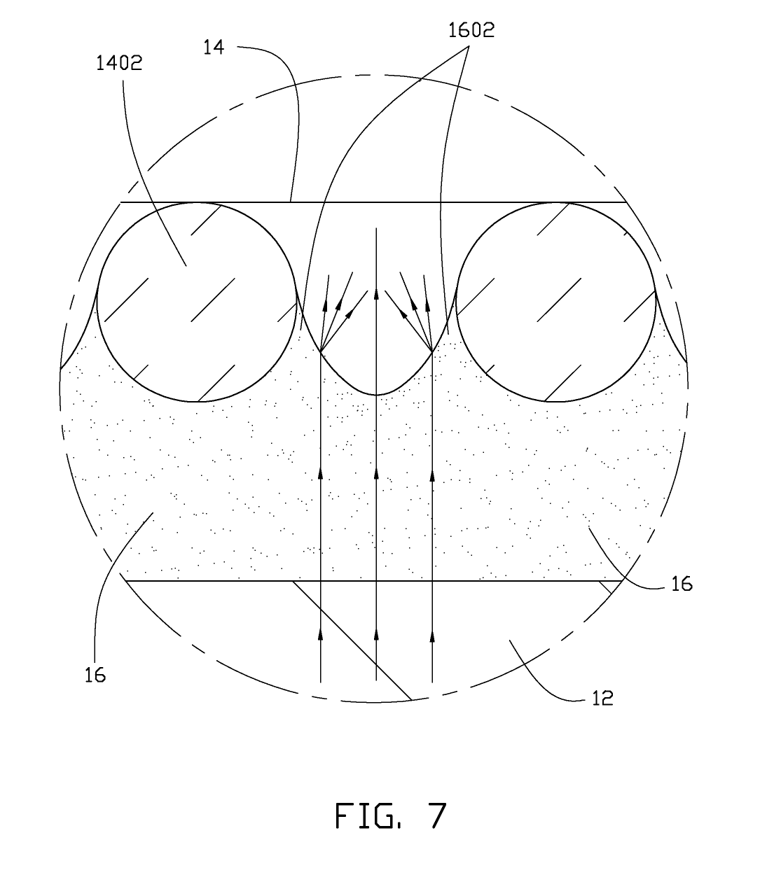

Referring to FIG. 6 and FIG. 7, the surface roughness Ra of the transparent conductive layer 14 exceeds 0.1 μm. A portion of the adhesive layer 16 is filled in the micropores of the adjacent carbon nanotubes 1402. The adhesive layer 16 close to the carbon nanotubes 1402 rises to surfaces of the adjacent carbon nanotubes 1402 under surface tensions therebetween. A surface of the adhesive layer 16 in the center of the adjacent carbon nanotubes 1402 is lower than that of close to the adjacent carbon nanotubes 1402. Such that, concave-like structures 1602 are formed on a surface of the adhesive layer 16. Each concave-like structure 1602 is similar to two triple prisms. Chromatic dispersion frequently occurs when light passes through the triple prisms. A refractivity of the adhesive layer 16 is much different from that of vacuum, so when multiple beams enter the substrate 12, the concave-like structures 1602 function as triple prisms. When the multiple beams pass through the adhesive layer 16, part of the light is split into individual beams, such that color fringes on the touch panel 10 become visible, thereby affecting the resolution of the touch panel 10. To reduce or avoid the color fringe, the surface roughness Ra of the transparent conductive layer 14, and accordingly, of the carbon nanotube layer should be less than or equal to 0.1 μm. Specifically, the surface roughness Ra of the carbon nanotube layer should be less than or equal to 0.01 μm.

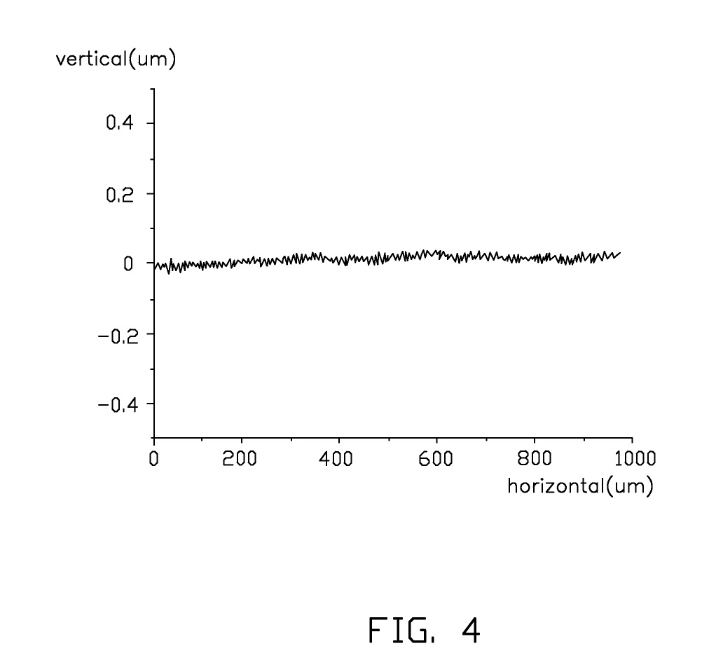

In one embodiment, the transparent conductive layer 14 is a layer of drawn carbon nanotube film with a thickness of 150 nm. A surface roughness Ra of the drawn carbon nanotube film is about 0.005 μm. Referring to FIG. 4 and FIG. 5, the surface roughness Ra of the transparent conductive layer 14 is about 0.005 μm. The micropores defined among the adjacent carbon nanotubes 1402 of the transparent conductive layer 14 are filled with the material of the adhesive layer 16, rendering the surface thereof substantially flat without any concave-convex structures. Surfaces of the carbon nanotubes 1402 and of the adhesive layer 16 are substantially coplanar, such that the surface of the transparent conductive layer 14 is substantially smooth and flat. Multiple beams passing through the substrate 12 and the adhesive layer 16 result in minimal or even no refraction. Thus, minimal or no color fringe is visible on the touch panel 10, improving resolution thereof.

The two first electrodes 18 are separately located at the transparent conductive layer 14 or the substrate 12. A direction from one of the first-electrodes 18 across the transparent conductive layer 14 or the substrate 12 to the other first electrode 18 is defined as a first direction X, as shown in FIG. 1. The second electrodes 17 are separately located at the transparent conductive layer 14 or the substrate 12. A second direction Y extends from one of the second-electrodes 17 across the transparent conductive layer 14 or the substrate 12 to the other second electrode 17, as shown in FIG. 1. The two first electrodes 18 and the two second electrodes 17 are placed on the transparent conductive layer 14 or the substrate 12, to form a uniform resistive net on the transparent conductive layer 14. The first electrodes 18 and the second electrodes 17 are made of metal, conductive resin, carbon nanotube film, or any other conductive material, so long as it is electrically conductive. In one embodiment, the Y direction is substantially perpendicular to the X direction, that is, the two first electrodes 18 are orthogonal to the two second electrodes 17. The first electrodes 18 and the second electrodes 17 are located at the transparent conductive layer 14, and made of silver paste.

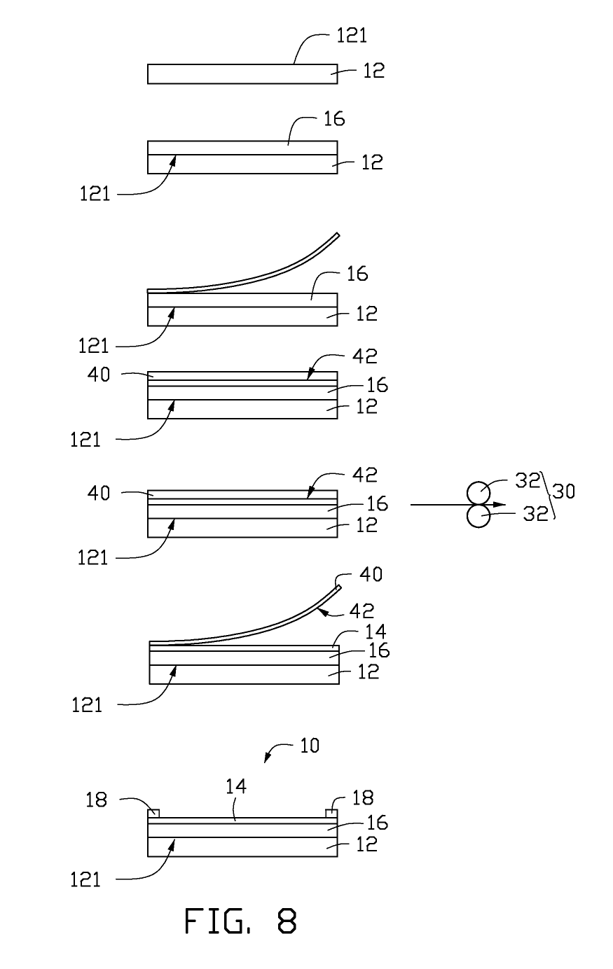

Referring to FIG. 8, one embodiment of a fabrication method for a touch panel 10 is provided, as follows:

(w10) providing the substrate 12 having the top surface 121;

(w20) forming the adhesive layer 16 on the top surface 121 of the substrate 12;

(w30) forming the carbon nanotube layer as the transparent conductive layer 14 on the adhesive layer 16;

(w40) applying a pressure on the carbon nanotube layer to bury part of the carbon nanotube layer in the adhesive layer 16, so that the surface roughness Ra of the carbon nanotube layer is less than or equal to 0.1 μm;

(w50) solidifying the adhesive layer 16; and

(w60) forming the two first electrodes 18 and the two second electrodes 17.

In step (w10), the top surface 121 of the substrate 12 is cleaned by ethanol, acetone, or other organic solvent, to ensure the top surface 121 is free from contamination.

In step (w20), the adhesive layer 16 is formed by coating thermoplastic adhesive or ultraviolet rays adhesive on the top surface 121 of the substrate 12.

Step (w30) can include the following substeps: (w31) providing at least one carbon nanotube film; and (w32) laying the at least one carbon nanotube film on the adhesive layer 16 to form the carbon nanotube layer.

In one embodiment, the carbon nanotube film in step (w31) is a drawn carbon nanotube film made by the following steps:

(a) providing a carbon nanotube array;

(b) pulling out a drawn carbon nanotube film from the array of carbon nanotubes; and

(c) irradiating the drawn carbon nanotube film using a laser.

In step (a), the carbon nanotube array is composed of a plurality of carbon nanotubes. The plurality of carbon nanotubes can be single-walled carbon nanotubes, double-walled nanotubes, multi-walled carbon nanotubes, or any combination thereof. In one embodiment, the plurality of carbon nanotubes comprises substantially parallel multi-walled carbon nanotubes. The carbon nanotube array is essentially free of impurities, such as carbonaceous or residual catalyst particles. The carbon nanotube array can be a super aligned carbon nanotube array. A method for making the carbon nanotube array is unrestricted, and can be by chemical vapor deposition methods or other methods.

Step (b) can be realized by selecting one or more carbon nanotubes having a predetermined width from the array of carbon nanotubes; and pulling the carbon nanotubes at a uniform speed to form carbon nanotube segments that are joined end to end to achieve a uniform drawn carbon nanotube film.

The carbon nanotube segments can be selected by using a tool allowing multiple carbon nanotubes to be gripped and pulled simultaneously to contact the array of carbon nanotubes. The pulling direction can be substantially perpendicular to the growing direction of the array of carbon nanotubes.

More specifically, during the pulling process, as the initial carbon nanotube segments are drawn out, other carbon nanotube segments are also drawn out end to end due to van der Waals force between ends of adjacent segments. This process of pulling produces a substantially continuous and uniform carbon nanotube film having a predetermined width. If the angle between the aligned directions of the carbon nanotubes in adjacent carbon nanotube films is larger than 0 degrees, a microporous structure is defined. The carbon nanotube structure in an embodiment employing these films comprises a plurality of micropores with diameter which can range from about 1 nm to about 0.5 mm. Stacking the carbon nanotube films adds to the structural integrity of the carbon nanotube structure.

Step (c) is configured for improving light transmittance of the drawn carbon nanotube film. Because of the van der Waals force, the carbon nanotubes in the drawn carbon nanotube film easily bundle together to form carbon nanotube strings with a large diameter. The carbon nanotube strings have relatively low light transmittance and thus affect the light transmittance of the drawn carbon nanotube film 141. A laser with a power density greater than 0.1×10⁴ W/m² can irradiate the drawn carbon nanotube film, removing the carbon nanotube strings having a low light transmittance and improving light transmittance of the drawn carbon nanotube film. Step (c) can be executed in an oxygen comprising atmosphere. In one embodiment, step (c) is executed in an ambient atmosphere. It is also understood that the laser treatment can be used on any carbon nanotube film.

Step (c) can be executed by many methods. In one method, the drawn carbon nanotube film is fixed and a laser device moving at an even/uniform speed is used to irradiate the fixed drawn carbon nanotube film. In another method, the laser device is fixed, and the drawn carbon nanotube film is moved through the light of the laser.

The carbon nanotubes absorb energy from the laser irradiation and a temperature of the drawn carbon nanotube film is increased. The laser irradiation can target the carbon nanotube strings with larger diameters, because they will absorb more energy and be destroyed, leaving strings with smaller diameters and higher light transmittance, resulting in a drawn carbon nanotube film having a relatively higher light transmittance. The relatively higher light transmittance can be greater than 70% higher, and in certain embodiments, it can be greater than 85%.

In step (w32), the carbon nanotube layer can include a single carbon nanotube film, or a plurality of carbon nanotube films. In one embodiment, the carbon nanotube layer is a drawn carbon nanotube film. The carbon nanotube layer is formed by laying the drawn carbon nanotube film on the adhesive layer 16 before the adhesive layer 16 has solidified. The carbon nanotube layer is attached to the adhesive layer 16 entirely. In one embodiment, the carbon nanotube layer includes a plurality of drawn carbon nanotube film, and the carbon nanotube layer is formed by arranging the plurality of drawn carbon nanotube films side by side or stacking the plurality of drawn carbon nanotube films on the adhesive layer 16 before solidification thereof.

If the adhesive layer 16 is not solidified, the carbon nanotube layer floats thereon, so that the surface roughness Ra of the carbon nanotube layer exceeds about 0.1 μm. If the adhesive layer 16 is solidified without subsequent pressing, the surface of the carbon nanotube layer is fluctuant, as shown in FIGS. 6 and 7. Thus, a touch panel using the carbon nanotube layer as a transparent conductive layer can produce color fringes.

Step (w40) can include the following substeps:

(w41) providing a press tool 40 with a flat surface 42; and

(w42) pressing the carbon nanotube layer using the press tool 40.

In step (w41), the press tool 40 can enable the surface roughness Ra of the transparent conductive layer 14 to be less than or equal to about 0.1 μm, the less the better. The surface roughness Ra of the flat surface 42 is less than or equal to about 0.1 μm. Specifically, the surface roughness Ra of the flat surface 42 is less than or equal to about 0.01 μm. The press tool 40 may be a PC film, PES film, cellulose ester film, PVC film, BCB film or acrylic resins film. In one embodiment, the surface roughness Ra of the flat surface 42 of the press tool 40 is less than 0.05 μm. The press tool 40 is a PC film. A shape and material of the press tool 40 is not limited. Any press tool 40 having at least one flat surface 42 can be used.

In step (w42), the flat surface 42 of the press tool 40 is attached to the carbon nanotube layer. The press tool 40 applies uniform pressure on the carbon nanotube layer. Because the carbon nanotube layer is floating on the adhesive layer 16 before the adhesive layer 16 is solidified, the carbon nanotubes in the carbon nanotube layer can immerge in the adhesive layer 16 under the uniform pressure. As such, the surface roughness Ra of the carbon nanotube layer can be less than or equal to about 0.1 μm after the adhesive layer 16 is solidified.

More specifically, the substrate 12 with the carbon nanotube layer and the press tool 40 laid thereon can be pressed by a press device 30. The press device 30 has two metal rollers 32. The substrate 12 with the carbon nanotube layer and the press tool 40 laid thereon is squeezed by the two metal rollers 32 of the press device 30. Speeds of the two metal rollers 32 can be selected according to need, so that the surface roughness Ra of the carbon nanotube layer can be less than or equal to 0.1 μm after being pressed by the press device 30. In one embodiment, the speeds of the two metal rollers 32 are in a range from about 1 millimeter per minute to about 10 meters per minute.

To make the surface roughness Ra of the carbon nanotube layer less than or equal to about 0.1 μm, the pressure should be uniformly applied on the carbon nanotube layer during the process of the pressing. When the pressure is uniformly applied on the press tool 40, the material of the adhesive layer 16 is filled in the micropores of the carbon nanotube layer. Simultaneously, air between the carbon nanotube layer and the flat surface 42 of the press tool 40 is squeezed out, which makes the carbon nanotube layer tightly attach to the flat surface 42 of the press tool 40. Because the surface roughness Ra of the flat surface 42 is less than or equal to about 0.1 μm, the surface roughness Ra of the surface of the carbon nanotube layer is less than or equal to about 0.1 μm. Thus, the pressure applied on the press tool 40 and the surface roughness Ra of the flat surface 42 are important factors to affect the surface roughness Ra of the carbon nanotube layer.

Step (w50) further includes a step of removing the press tool 40 from the carbon nanotube layer after the adhesive layer 16 is solidified. Because the surface roughness Ra of the flat surface 42 is less than or equal to about 0.1 μm, that is, the flat surface 42 is very smooth, it is easy to remove the press tool 40 from the carbon nanotube layer after the adhesive layer 16 is solidified. The press tool 40 can be removed by a mechanical force. After removing the press tool 40, the surface of the carbon nanotube layer, that is, the transparent conductive layer 14, is smooth with the surface roughness Ra less than or equal to about 0.1 μm. In one embodiment, the surface roughness Ra of the transparent conductive layer 14 is about 0.005 μm as shown in FIG. 5.

In step (w60), the two first electrodes 18 and the two second electrodes 17 are separately formed on and electrically connected to the transparent conductive layer 14, thereby forming the touch panel 10. In one embodiment, the first electrodes 18 and the two second electrodes 17 are formed by coating a conductive silver paste on the carbon nanotube layer to form four strip electrodes, and baking the substrate 12 in an oven for about 10 minutes to about 60 minutes at a temperature in an approximate range from about 100° C. to about 120° C. to solidify the conductive silver paste. Two of the four strip electrodes are separately formed on the carbon nanotube layer along the first direction X to form the two first electrodes 18, and the other two of the four strip electrodes are separately formed on the carbon nanotube layer along the second direction Y to form the two first electrodes 17.

The conductive silver paste also can be coated on the substrate 12 to form the two first electrodes 18 and the two second electrodes 17. Simultaneously, the two first electrodes 18 and the two second electrodes 17 are electrically connected to the transparent conductive layer 14.

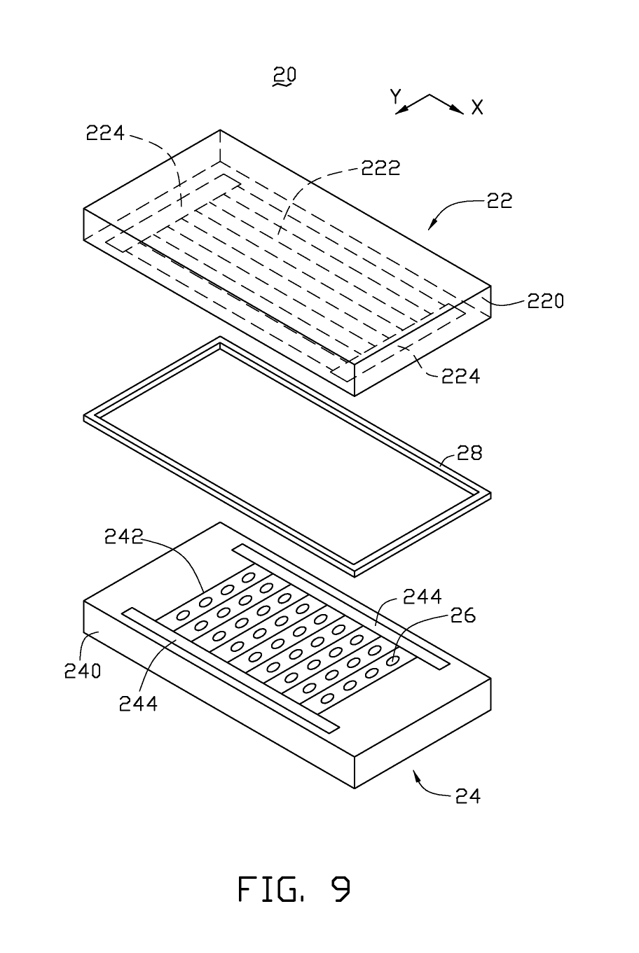

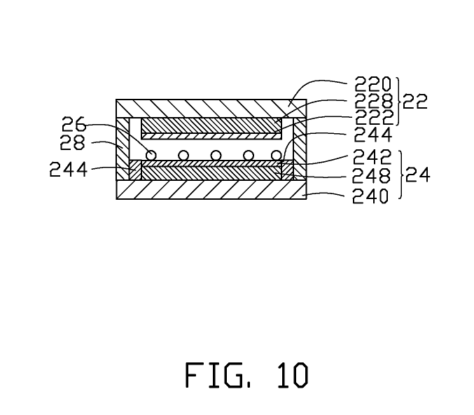

Referring to FIG. 9 and FIG. 10, one embodiment of a resistive-type touch panel 20 includes a first electrode plate 22, a second electrode plate 24, a plurality of transparent dot spacers 26, and an insulating frame 28. The first and second electrode plates 22, 24 are opposite to and spaced from each other by the insulating frame 28. The transparent dot spacers 26 are located between the first and second electrode plates 22, 24.

The first electrode plate 22 includes a first substrate 220, a first adhesive layer 228, a first transparent conductive layer 222, and two first electrodes 224. The first substrate 220 has a planar structure. The first transparent conductive layer 222 and the two first electrodes 224 are attached to a same surface of the first substrate 220. The first adhesive layer 228 is located between the first transparent conductive layer 224 and the first substrate 220. The two first electrodes 224 are electrically connected to the first transparent conductive layer 222. Specifically, the two first electrodes 224 are separately located at two ends of the first transparent conductive layer 222. A direction from one of the first-electrodes 224 across the first transparent conductive layer 222 to the other first electrode 224 is defined as a first direction X, as shown in FIG. 9.

The second electrode plate 24 includes a second substrate 240, a second adhesive layer 248, a second transparent conductive layer 242, and two second electrodes 244. The second substrate 240 has a planar structure. The second transparent conductive layer 242 and the two second electrodes 244 are located on the same surface of the second substrate 240. The second adhesive layer 248 is located between the second transparent conductive layer 244 and the second substrate 240. The first and second transparent conductive layer 222, 242 are located face to face, and spaced from each other with a predetermined distance. In one embodiment, the distance between the first transparent conductive layer 222 and the second transparent conductive layer 242 is from about 2 μm to 10 μm. The two second electrodes 244 are electrically connected to the second transparent conductive layer 242, and separately located on the second substrate 240 along two ends in a second direction. A direction from one of the second-electrodes 244 across the second transparent conductive layer 242 to the other second-electrodes 244 is defined as the second direction Y, which crosses or intersects with the first direction, as shown in FIG. 9. In one embodiment, the Y direction is substantially perpendicular to the X direction, that is, the two first electrodes 224 are orthogonal to the two second electrodes 244. The two second electrodes 244 are also electrically connected to the second transparent conductive layer 242.

The first substrate 220 can be a transparent and flexible film or a plate made of polymer, resin, or any other suitable flexible material. The second substrate 240 can be a rigid and transparent board made of glass, diamond, quartz, plastic, or any other suitable material. The second substrate 240 can also be a transparent flexible film or plate similar to the first substrate 220. A thickness of the first substrate 220 and the second substrate 240 can be in a range from about 1 mm to about 1 centimeter (cm). In one embodiment, the first and second substrates 120, 140 are made of PET, and have a thickness of about 2 mm.

The first adhesive layer 228 can be configured for adhering the first transparent conductive layer 222 onto the first substrate 220. The second adhesive layer 248 can be used for adhering the second transparent conductive layer 242 onto the second substrate 240. Functions and structures of the first and second adhesive layers 228, 248 are similar to those of the adhesive layer 16 described. Materials of the first and second adhesive layers 228, 248 have low melting point, and can be thermoplastic adhesive or ultraviolet rays adhesive, such as PVC, PMMA. In one embodiment, the first and second adhesive layer 228, 248 are made of PMMA.

The first transparent conductive layers 222 can be the carbon nanotube layer, having the characteristic of transparency and electrical conduction. The carbon nanotube layer can include a plurality of carbon nanotubes, substantially parallel to a surface of the carbon nanotube layer with a surface roughness Ra thereof less than or equal to about 0.1 μm. Specifically, the surface roughness Ra of the carbon nanotube layer may be less than or equal to about 0.01 μm. Adjacent carbon nanotubes in the carbon nanotube layer define a plurality of micropores. A material of the second transparent conductive layer 242 can be transparent and electrically conductive. The second transparent conductive layer 242 can be the carbon nanotube layer, or other transparent conductive materials, such as ITO and antimony tin oxide (ATO). When the second transparent conductive layer 242 is ITO, ATO, or other transparent conductive materials, the second adhesive layer 248 may not be needed to fix the second transparent conductive layer 242 on the second substrate 240. In one embodiment, structures of both the first and second transparent conductive layers 222, 242 are the same as that of the transparent conductive layer 14 of the touch panel 10.

The drawn carbon nanotube film has a plurality of micropores defined by the adjacent carbon nanotubes thereof. A part of the first adhesive layer 228 is formed in the micropores of the first transparent conductive layer 222. A surface of the part of the first adhesive layer 228 filled in the micropores is substantially flat and has no concave-like structures. The first transparent conductive layer 222 is attached on the first substrate 220 by the first adhesive layer 228. A part of the first transparent conductive layer 222 is embedded in the first adhesive layer 228 under pressure, and the other part of the first transparent conductive layer 222 is exposed to the first adhesive layer 228 so that the first transparent conductive layer 222 is electrically conductive. A surface of the first adhesive layer 228 filled in the first transparent conductive layer 222 and a surface of the first transparent conductive layer 222 are substantially coplanar, such that light passing through the first adhesive layer 228 generates only minimal refraction or none.

The structure and material of the second electrode plate 24 are almost the same as those of the first electrode plate 22. The material of the second adhesive layer 248 is filled in a plurality of micropores defined by adjacent carbon nanotubes in the second transparent conductive layer 242. A surface of the second adhesive layer 248 filled in the second transparent conductive layer 242 and a surface of the second transparent conductive layer 242 are substantially coplanar. The surface of the second adhesive layer 248 has no concave-like structures. As such, light from the first electrode plate 22 passing through the second adhesive layer 248 generates minimal refraction or none at all, thereby improving the resolution of the touch panel 20.

The first electrodes 224 and the second electrodes 244 are made of metal, conductive resin, carbon nanotube film, or any other electrically conductive material. In one embodiment, both the first and second electrodes 224, 244 are made of silver paste. It is noted that the electrodes of a flexible touch panel should be strong but flexible.

The transparent dot spacers 26 are separately located on the second transparent conductive layer 242. The insulating frame 28 is mounted between the first substrate 220 and the second substrate 240. The transparent dot spacers 26 and the insulating frame 28 are made of, for example, insulating resin or any other suitable insulating material. Insulation between the first electrode plate 22 and the second electrode plate 24 is provided by the transparent dot spacers 26 and the insulating frame 28. It is to be understood that the transparent dot spacers 26 are optional, particularly when the touch panel 20 is relatively small.

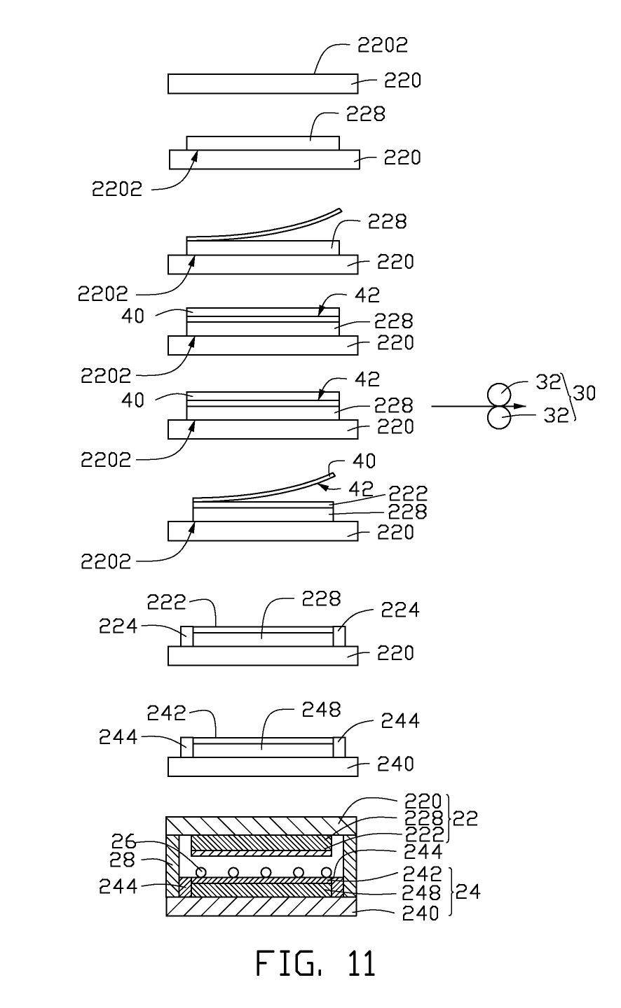

FIG. 11 illustrates steps of one embodiment of a fabrication method of a touch panel, such as, for example, that of FIG. 9. The method includes the following steps:

(s10) providing the first substrate 220;

(s20) forming the first adhesive layer 228 on the substrate 220;

(s30) forming the carbon nanotube layer as the first transparent conductive layer 222 on the first adhesive layer 228;

(s40) applying a pressure on the carbon nanotube layer to bury a part of the carbon nanotube layer in the first adhesive layer 228, so that the surface roughness Ra of the carbon nanotube layer is less than or equal to about 0.1 μm;

(s50) solidifying the first adhesive layer 228;

(s60) separately forming the two first electrodes 224 electrically connected to the first transparent conductive layer 222, thereby forming the first electrode plate 22;

(s70) forming the second electrode plate 24 by providing the second substrate 240, and applying the second transparent conductive layer 242 on the second substrate 240; and

(s80) securing the first electrode plate 22 to the second electrode plate 24, wherein the first transparent conductive layer 222 faces the second transparent conductive layer 242, thereby forming the touch panel 20.

Step (s10) to step (s60) can be executed in the same manner as that of step (w10) to step (w60) of the touch panel 10.

In step (s70), steps (s10) to (s60) are repeated, the second electrode plate 24 further includes the two second electrodes 244 electrically connected to the second transparent conductive layer 242, and the second adhesive layer 248 is placed on the second substrate 240.

It can be understood that when the material of the second transparent conductive layer 242 is ITO, ATO, or other transparent conductive materials. A slurry of the material of the second transparent conductive layer 242 can be formed on the second substrate 220 by coating, printing, or spinning without the second adhesive layer 248. The second electrode plate 24 can be formed after the second substrate 220 with the slurry thereon is baked.

Step (s80) may include the following steps: (s81) placing the insulating frame 28 on the first electrode plate 22 periphery with the first transparent conductive layer 222 formed thereon, (s82) forming a plurality of transparent dot spacers 26 on the second electrode plate 24; and (s83) placing the second electrode plate 24 on the insulating frame 28.

In step (s81), the insulating frame 28 can be formed by coating a layer of insulating adherent agent on the edges of the first electrode plate 22 or the first substrate 220. Alternatively, the insulating frame 28 also can be formed on the second electrode plate 24.

In step (s82), the plurality of transparent dot spacers 26 is formed by coating a layer of slurry comprising of the plurality of transparent dot spacers 26 on the portion of the second electrode plate 24 without the insulating frame 28 defined thereon, and drying the layer of slurry to form the plurality of transparent dot spacers 26. The plurality of transparent dot spacers 26 can also be formed on the first electrode plate 22 without the insulating frame 28 defined thereon.

In step (s83), the two first electrodes 224 in the first electrode plate 22 are separately arranged along a first direction, and the two second electrodes 244 in the second electrode plate 24 are separately arranged along a second direction intersecting with the first direction.

As disclosed, the surface of the transparent conductive layers are flat, with surface roughness Ra thereof less than or equal to about 0.1 μm, such that when light passes therethrough, refraction resulting therefrom is minimal, or even absent, and only minor or no color fringes appear, thereby improving the resolution of the touch panel. Secondly, because the carbon nanotube layer has superior strength, and uniform conductivity, the carbon nanotube layer can be used as the transparent conductive layers; the touch panels using the transparent conductive layers are durable and highly reliable.

As disclosed, the fabrication method for the touch panels is simple and avoids formation of color fringes, thereby improving the resolutions of the touch panels. The pulling method for fabricating the carbon nanotube film is also simple because the method for fabricating the carbon nanotube film requires no vacuum environment or heating process. As such, the touch panel produced by the present method has advantages such as low cost, environmentally safe, and is energy efficient. Further, when the carbon nanotube layer is an ordered carbon nanotube layer, it is easy to control the directions of the carbon nanotubes in the carbon nanotube layer.

It is to be understood that the embodiments disclosed are intended to illustrate rather than limit the disclosure. Variations may be made to the embodiment without departing from the spirit of the disclosure as claimed. The above-described embodiments are intended to illustrate the scope of the disclosure and not restricted to the scope of the disclosure.

Depending on the embodiment, certain steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for steps.

What is claimed is:

1. A touch panel, comprising:
a substrate comprising a surface;
an adhesive layer disposed on the surface of the substrate;
a transparent conductive layer fixed on the surface of the substrate by the adhesive layer, wherein the transparent conductive layer comprises a carbon nanotube layer with a surface roughness Ra less than or equal to about 0.1 micrometers;
two first electrodes separated from each other and electrically connected to the transparent conductive layer; and
two second electrodes separated from each other and electrically connected to the transparent conductive layer.

2. The touch panel as claimed in claim 1, wherein a first part of the carbon nanotube layer is embedded in the adhesive layer, and a second part of the carbon nanotube layer is exposed to the adhesive layer.

3. The touch panel as claimed in claim 2, wherein the surface roughness Ra of the carbon nanotube layer exposed to the adhesive layer is less than or equal to about 0.01 micrometers.

4. The touch panel as claimed in claim 1, wherein the carbon nanotube layer comprises a plurality of carbon nanotubes partly embedded in the adhesive layer and partly exposed to the adhesive layer.

5. The touch panel as claimed in claim 4, wherein a plurality of micropores is defined by the plurality of carbon nanotubes, a material of the adhesive layer is filled in the plurality of micropores, and a surface of the adhesive layer filled in the plurality of micropores is substantially flat.

6. The touch panel as claimed in claim 5, wherein the surface of the adhesive layer filled in the plurality of micropores and a surface of the carbon nanotube layer are substantially coplanar.

7. The touch panel as claimed in claim 5, wherein the plurality of carbon nanotubes in the carbon nanotube layer is substantially parallel to the carbon nanotube layer.

8. The touch panel as claimed in claim 1, wherein a thickness of the carbon nanotube layer ranges from about 100 nm to about 200 nm.

9. The touch panel as claimed in claim 1, wherein a material of the adhesive layer is thermoplastic adhesive or ultraviolet rays adhesive.

10. The touch panel as claimed in claim 1, wherein the two first electrodes are separated from each other along a first direction, and the two second electrodes are separated from each other along a second direction intersecting with the first direction.

11. A touch panel, comprising:
a first electrode plate comprising:
a first substrate;
an adhesive layer; and
a first transparent conductive layer fixed on the first substrate by the adhesive layer, wherein the first transparent conductive layer comprises a carbon nanotube layer with a surface roughness Ra less than or equal to about 0.1 micrometers;
a second electrode plate spaced from the first electrode plate and comprising:
a second substrate; and
a second transparent conductive layer disposed on the second substrate, the second transparent conductive layer being opposite to the first transparent conductive layer.

12. The touch panel as claimed in claim 11, wherein a first part of the carbon nanotube layer is embedded in the adhesive layer, and a second part of the carbon nanotube layer is exposed to the adhesive layer.

13. The touch panel as claimed in claim 11, wherein the carbon nanotube layer comprises a plurality of carbon nanotubes partly embedded in the adhesive layer and partly exposed to the adhesive layer.

14. The touch panel as claimed in claim 13, wherein a plurality of micropores is defined by the plurality of carbon nanotubes, a material of the adhesive layer is filled in the plurality of micropores, and a surface of the adhesive layer filled in the plurality of micropores is substantially flat.

15. The touch panel as claimed in claim 14, wherein the surface of the adhesive layer filled in the plurality of micropores and a surface of the carbon nanotube layer are substantially coplanar.

16. A fabrication method for a touch panel, comprising:
(a) providing a first substrate comprising a surface;
(b) forming a first adhesive layer on the surface of the first substrate;
(c) forming a carbon nanotube layer as a first transparent conductive layer on the first adhesive layer;
(d) applying pressure on the carbon nanotube layer to embed a part of the carbon nanotube layer in the first adhesive layer, so that a surface roughness Ra of the carbon nanotube layer less than or equal to 0.1 micrometers;
(e) solidifying the first adhesive layer; and
(f) forming at least two first electrodes separately and electrically connected to the transparent conductive layer.

17. The method as claimed in claim 16, wherein step (d) comprises providing a press tool with a flat surface to which a surface of the carbon nanotube layer is attached, and applying uniform pressure on the press tool.

18. The method as claimed in claim 16, wherein a surface roughness Ra of the flat surface of the press tool is less than or equal to about 0.1 micrometers.

19. The method as claimed in claim 16, further comprising a step (g) of forming a second electrode plate comprising a second substrate, a second transparent conductive layer, and two second electrodes; and a step (h) of securing a first electrode plate to the second electrode plate, wherein the first electrode plate comprises the first substrate, the adhesive layer, the first transparent conductive layer, and the two first electrodes, formed by steps (a) through (f), and the first transparent conductive layer faces and is spaced from the second transparent conductive layer.

20. The method as claimed in claim 16, further comprising a step (g) of forming a second electrode plate comprising a second transparent conductive layer by steps (a) to (f); and a step (h) of securing a first electrode plate to the second electrode plate, wherein the first electrode plate is formed by step (a) to step (f), and the first transparent conductive layer faces and is spaced from the second transparent conductive layer.
